(19) United States
(12) Patent Application Publication
(10) Pub. No.: US 2010/0294363 A1
(43) Pub. Date: Nov. 25, 2010

(54) Coated Polyester Film For Lamination to Ethylene-Vinyl Acetate Layers

(75) Inventor: Stephen J. Gust, Greenville, SC (US)

Correspondence Address: DORITY & MANNING, P.A., POST OFFICE BOX 1449, GREENVILLE, SC, 29602-1449, US

(73) Assignee: Mitsubishi Polyester Film, Inc., Greer, SC (US)

(21) Appl. No.: 12/785,112

(22) Filed: May 21, 2010

Related U.S. Application Data
(60) Provisional application No. 61/180,590, filed on May 22, 2009.

(51) Int. Cl. H01L 31/0203; B32B 27/36; B32B 27/08

(52) U.S. Cl. 136/259; 428/447; 428/423.7; 428/341

(57) ABSTRACT

A bonding material is described that is well suited to bonding polymer films, such as polyester films, to other substrates. In one embodiment, for instance, the bonding material can be used to bond a polyester film to a layer containing an ethylene-vinyl acetate copolymer to form a backing material for a photovoltaic device. The bonding material generally comprises a block copolymer combined with a coupling agent. The block copolymer generally contains a polyester segment in combination with a different polymer segment. The different polymer segment may comprise, for instance, polyethylene glycol polymer blocks. The coupling agent, on the other hand, can comprise a functional silane. The polyester segments on the block copolymer attach to the polyester film, while the silane coupling agent reacts with the second polymer blocks and reacts with a constitutent in an adjacent layer.

### BACKGROUND

Photovoltaic devices convert light energy, such as sunlight, into electricity. Photovoltaic devices typically include one or more solar cells that contain a semiconductor material. The semiconductor material may comprise, for instance, silicon or any other suitable material. When light energy strikes the solar cell, the semiconductor material can produce an electric current if connected to an electric circuit. A number of solar cells electrically connected to each other and mounted in a support structure is typically referred to as a photovoltaic module. A photovoltaic array, on the other hand, can comprise a plurality of modules.

The solar cells are typically placed behind a transparent material, such as a glass sheet. On the opposite side, the solar cell typically includes a backing material that is intended to protect the solar cell during operation. The backing material, for instance, should be capable of providing moisture resistance and/or heat resistance. The backing material should also be capable of providing some structure and should comprise a material having electrical insulation properties.

In the past, the backing material has comprised various different types of laminates. In one embodiment, for instance, the backing material has comprised an ethylene-vinyl acetate copolymer layer laminated to a polyester film. The ethylene-vinyl acetate copolymer layer acts as potting aid for the solar cells. The polyester film, on the other hand, provides further protection and is a very good insulator. Problems have been experienced, however, in attaching the polyester film to the layer containing the ethylene-vinyl acetate copolymer.

In the past, in order to improve the adhesion between the two layers, various different adhesives have been proposed. For example, U.S. Patent Application Publication No. 2008/0050583, which is incorporated herein by reference, proposes the use of a resin film comprising a cross-linking agent and a resin selected from the group consisting of a polyester resin, an acrylic resin, a combination of the resins, or a combination of at least one of the resins and a polyvinyl alcohol.

In Japanese Patent Application No. 2006-332091 an adhesion promoter is disclosed which consists of an acrylic resin, an epoxy system resin, a phenol system resin, a polyester system resin, a urethane system resin, or a styrene system resin chemically combined with a silane. In another embodiment, a silane has been combined with a sulfonated polyester in order to form an adhesive layer between the polyester film and the ethylene-vinyl acetate copolymer.

Prior adhesive compositions, however, have failed to provide sufficient bonding strength between the ethylene-vinyl acetate copolymer and the polyester film. Such prior adhesives have also been prone to lose bond strength when subjected to higher temperatures at higher humidities, which are common conditions in which solar cells are typically placed. As such, a need currently exists for an improved bonding material between a polymer film, such as a polyester film, and a layer containing an ethylene-vinyl acetate copolymer.

### SUMMARY

The present disclosure is generally directed to a coating that can be applied to a polyester film for improving adhesion between the polyester film and a layer containing an ethylene-vinyl acetate copolymer. Of particular advantage, the coating is capable of retaining a relatively great amount of its initial bond strength between the two layers even after exposure for many hours to an environment at a relatively high temperature and at relatively high humidity levels. The coated polyester film is particularly well suited for use in constructing backing materials for solar cells, solar modules and solar arrays. It should be understood, however, that the coated polyester film also has numerous other uses.

In one embodiment, for instance, the present disclosure is directed to a coated film that comprises a polyester film having a first side and a second side. A coating is located on the first side of the polyester film. In accordance with the present disclosure, the coating comprises a block copolymer combined with a silane. The block copolymer contains at least first polymer blocks and second polymer blocks. The first polymer blocks may comprise polyester blocks. The polyester blocks are attached to the first side of the polyester film. In one particular embodiment, for instance, the polyester blocks become “absorbed” into the polyester film during production of the film.

As described above, the coating further contains a silane. The silane includes a moiety that is chemically reactive with the second polymer blocks contained in the block copolymer. The silane is also capable of attaching to a layer containing an ethylene-vinyl acetate copolymer. For example, in one embodiment, the silane may bond with the block copolymer and functional groups contained within the opposing layer.

In one embodiment, the silane may comprise a glycidoxy silane. Alternatively, the silane may comprise an amino silane. The second polymer blocks contained in the block copolymer, on the other hand, may comprise polyethylene glycol blocks, urethane blocks, vinyl blocks, or polyethylene blocks.

In one embodiment, the polyester film is at least uniaxially stretched. For example, in one embodiment, the film can be biaxially stretched, In order to form the coating on the first side of the film, a coating composition can be applied to the film prior to complete stretching of the film. For instance, in one embodiment, the coating can be applied prior to stretching the film in the cross-direction. During stretching, the coating composition is heated and dried causing a coating to form on the film.

As described above, the coating generally comprises a block copolymer combined with a silane. In one embodiment, the block copolymer can be present in the coating in an amount from about 40% to about 99.9% by weight, such as from about 70% to about 99% by weight. The silane, on the other hand, can be present in the coating in an amount from about 0.1% to about 60% by weight.

The thickness of the coating and the amount of coating composition applied to the polyester film can vary depending upon the particular application. In one embodiment, for instance, the dry coating is present on the first side of the film in an amount from about 1×10⁻³ lbs/1,000 ft² to about 8×10⁻³ lbs/1,000 ft² of film.

In addition to a coated film, the present disclosure is also directed to a laminate comprising a polyester film bonded to a polymeric layer. The polymeric layer, in one embodiment, contains an ethylene-vinyl acetate copolymer. In other embodiments, however, the polymeric layer may contain various other polymers. For example, the polymeric layer may comprise a polyolefin polymer, such as a low density polyethylene, polypropylene, or copolymers thereof. In still other embodiments, the polymeric layer may comprise an ionomer or may comprise a thermoplastic elastomer. The laminate, for instance, may be used as a backing material for solar cells. In accordance with the present disclosure, the polyester film is attached to the polymeric layer by applying in between the two layers a bonding layer. The bonding layer comprises a block copolymer in combination with a silane as described above. The block copolymer attaches to the surface of the polyester film, while the silane, in one embodiment, chemically reacts with the block copolymer and at least one constituent in the polymeric layer.

The bonding layer is capable of forming strong bonds between the polyester film and the polymeric layer. For instance, the initial bond strength between the polyester film and the polymeric layer can be at least about 50 N/15 mm.

In addition to having excellent initial bond strength characteristics, the bonding layer is also capable of retaining its bond strength between the layers even after exposure to relatively high temperatures and to relatively high humidity levels for extended periods of time. For example, in one embodiment, the bond strength between the polyester film and the polymeric layer is at least about 50% of the initial bond strength, such as at least about 60% of the initial bond strength after exposure to an environment at 85% relative humidity at 85° C. for 1,000 hours.

The above described laminate can be used as a backing layer for photovoltaic devices. In one embodiment, for instance, the photovoltaic device includes a layer comprised of a semiconductor material that is capable of converting light energy into an electric current. The semiconductor material can be covered by a transparent panel, such as a glass panel that allows light energy to reach the semiconductor material while providing protection. On the opposite side of the semiconductor material, the photovoltaic device can include a backing layer comprising a laminate as described above.

Other features and aspects of the present disclosure are discussed in greater detail below.

### BRIEF DESCRIPTION OF THE DRAWINGS

A full and enabling disclosure of the present invention, including the best mode thereof to one skilled in the art, is set forth more particularly in the remainder of the specification, including reference to the accompanying figures, in which:

FIG. 1 is a perspective view of one embodiment of a photovoltaic device that may be made in accordance with the present disclosure;

FIG. 2 is a plan view of the back side of the photovoltaic device shown in FIG. 1;

FIG. 3 is a cross-sectional view of one embodiment of a photovoltaic device including a composite backing layer made in accordance with the present disclosure;

FIG. 4 is a cross-sectional view of one embodiment of a coated polymer film made in accordance with the present disclosure; and

FIGS. 5A and 5B are a plan view and a side view respectively of a sample preparation for conducting the peel test as described hereinafter.

Repeat use of reference characters in the present specification and drawings is intended to represent the same or analogous features or elements of the present invention.

### DETAILED DESCRIPTION

It is to be understood by one of ordinary skill in the art that the present discussion is a description of exemplary embodiments only, and is not intended as limiting the broader aspects of the present invention.

In general, the present disclosure is directed to a coated polymer film and particularly to a coated polyester film. The coating contained on the film is for attaching the film to other substrates or layers. For example, the coating is particularly well suited for attaching a polyester film to a layer containing an ethylene-vinyl acetate copolymer. Although the coated film may be used in numerous applications, in one embodiment, the film can be laminated to a layer containing an ethylene-vinyl acetate copolymer and used as a composite backing material for a photovoltaic device.

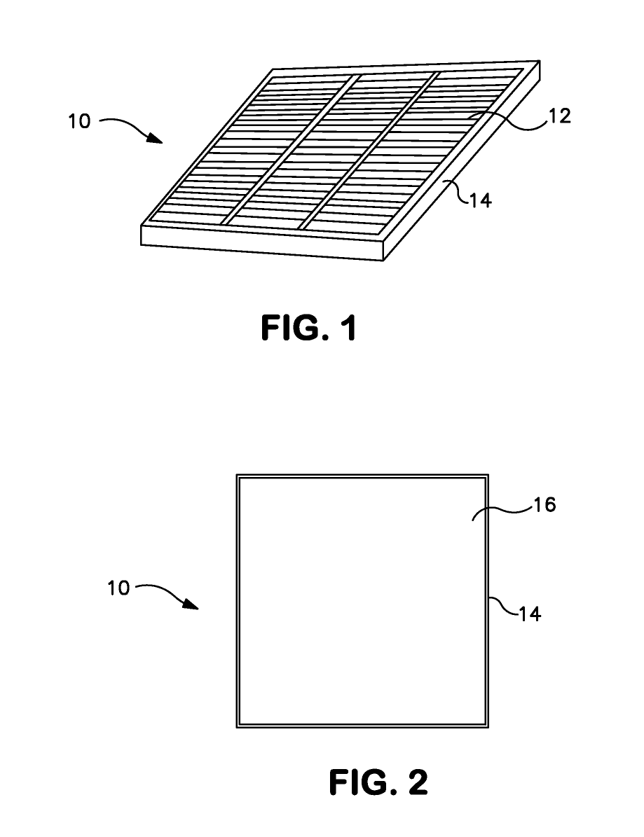

Referring to FIG. 1, for exemplary purposes only, a photovoltaic device 10 is illustrated. The photovoltaic device 10 can include one or more solar cells that are well suited to converting light energy, such as sunlight, into electricity.

In the embodiment illustrated in FIG. 1, the photovoltaic device 10 includes a semiconductor material 12 contained within a frame 14. The semiconductor material 12 is contained behind a transparent protective layer, such as a glass layer. An anti-reflective coating can be positioned in between the glass layer and the semiconductor material. The anti-reflective coating may be present in order to reduce the amount of light that is reflected and not used by the photovoltaic device. The transparent cover plate protects the device from the elements.

As shown, the semiconductor material 12 is divided into individual elements which may be considered individual solar cells. The semiconductor material 12 can be made from any suitable material capable of converting light energy into electricity. For instance, suitable materials that may be used to form the semiconductor material 12 may comprise silicon or gallium arsenide.

In one embodiment, the semiconductor material 12 may comprise two different layers: (1) an N-type semiconductor material layer, and (2) a P-type semiconductor material layer. For example, in one embodiment, both layers can be made from silicon. The two layers form a P-N junction photodiode. When exposed to sunlight, electrons may flow from the P-type layer to the N-type layer. When connected to an external current path, an electric current is then established, which can be conducted away from the photovoltaic device and used as desired. In this regard, the photovoltaic device can include a contact grid that establishes electrical connections.

Photovoltaic devices such as the one illustrated in FIG. 1 and various other solar panels are typically placed in outside environments at locations where there is ample amount of sunlight. Such environments typically have warm to hot temperatures. The environments can also be relatively humid. In order to protect the photovoltaic device from the elements, in addition to a top transparent plate, the devices typically include a composite backing material. In the past, backing materials have included a layer containing an ethylene-vinyl acetate copolymer laminated to a polymer film, such as a polyester film. The backing material provides moisture resistance while also having a relatively high dielectric constant.

Referring to FIG. 2, for instance, the back side of the photovoltaic device 10 is shown. As illustrated, the photovoltaic device includes a composite backing material 16 contained within the frame 14. In the past, various problems have been experienced in securely bonding polymer films, such as polyester films, to other polymeric films. In this regard, the present disclosure is directed to a bonding layer that can be placed between the two materials for greatly improving adhesion, especially when the backing material is subjected to higher temperatures at humid conditions for extended periods of time.

In one embodiment, the bonding material of the present disclosure can be applied to the polymer film as a coating prior to laminating the film to a polymeric layer. In general, the bonding material can be used to bond numerous different polymeric films together. For example, in one embodiment, the bonding material can be used to bond together a polyester film to a layer containing an ethylene-vinyl acetate copolymer. In other embodiments, the polymeric layer may comprise any suitable thermoplastic polymer, such as a polyolefin. For instance, the polymeric layer may comprise a polyethylene, such as linear low density polyethylene, a polypropylene, mixtures thereof, and copolymers thereof. In other embodiments, the polymeric layer may contain one or more ionomers or elastomers.

The bonding material of the present disclosure exhibits excellent initial bond strength. For example, the initial bond strength or peel strength between the polymer film layer and the layer containing the ethylene-vinyl acetate copolymer can be greater than about 50 N/15 mm, such as greater than about 60 N/15 mm, such as greater than about 70 N/15 mm. In one embodiment, for instance, the initial bond strength can be from about 50 N/15 mm to about 200 N/15 mm.

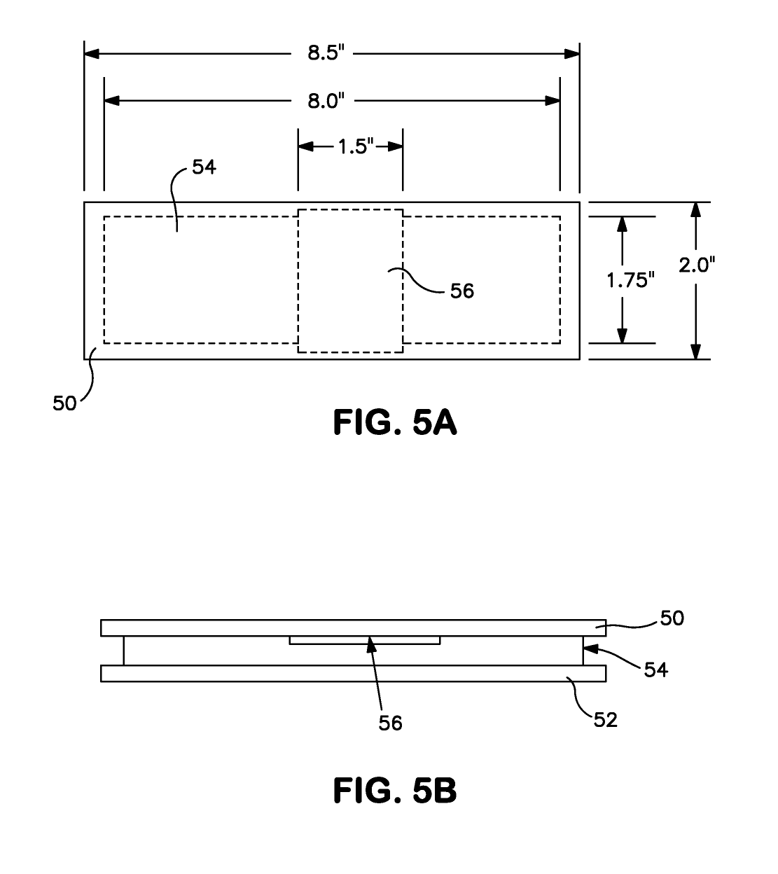

In order to determine the peel strength of a bonding material in accordance with the present disclosure, a sample as shown in FIGS. 5A and 5B is first prepared. As illustrated, the sample includes an ethylene-vinyl acetate layer 54 positioned in between two polyester film layers 50 and 52. A release sheet 56 is placed in between the polyester film layer 50 and the ethylene-vinyl acetate layer 54. The release sheet can comprise, for instance, a fabric coated with a fluorocarbon such as TEFLON polymer.

Once the layers are brought together as shown in FIGS. 5A and 5B, the sample is placed in a heat seal bar tester, such as the 12AS heat sealer sold by Sencorp having Model No. 5133505. The bar temperature is set at 300° F. and the sample is subjected to 2 psi of pressure for 0.5 minutes and 8 psi of pressure for 5.0 minutes. After being heat sealed, the sample is cured in a lab oven at 150° C. for 20 minutes. After being taken out of the lab oven, the sample is allowed to cool to room temperature.

Once the sample is prepared as shown in FIG. 5A, the sample is cut into four equal test strips. Specifically, the sample is cut lengthwise down the middle of the sample and widthwise down the middle of the sample. By including the release sheet 56 in the sample, a free edge of the polyester film 50 is formed when the sample is cut into the four strips.

Each of the four test strips is then placed in an Instron tensile testing machine. In particular, the free edge of the polyester film 50 where the release sheet 56 is located is placed in one jaw and the opposing portion of the sample comprised of the ethylene-vinyl acetate layer 54 and the polyester film 52 is placed in the opposite jaw. The Instron machine is set at a rate of 8 inches per minute. The machine indicates a peel strength in grams per 15 mm. All four test strips are tested and the four results are averaged.

In addition to displaying good initial bond strengths, the bonding material of the present disclosure is also capable of retaining most of the initial bond strength even when subjected to damp heat. For instance, the bonding material is capable of retaining at least 50% of its initial bond strength even when exposed to an environment at 85° C. and at 85% relative humidity for 1,000 hours. For instance, the bonding material may retain greater than 60%, such as greater than 70%, such as even greater than 80% of its initial bond strength when subjected to the above conditions.

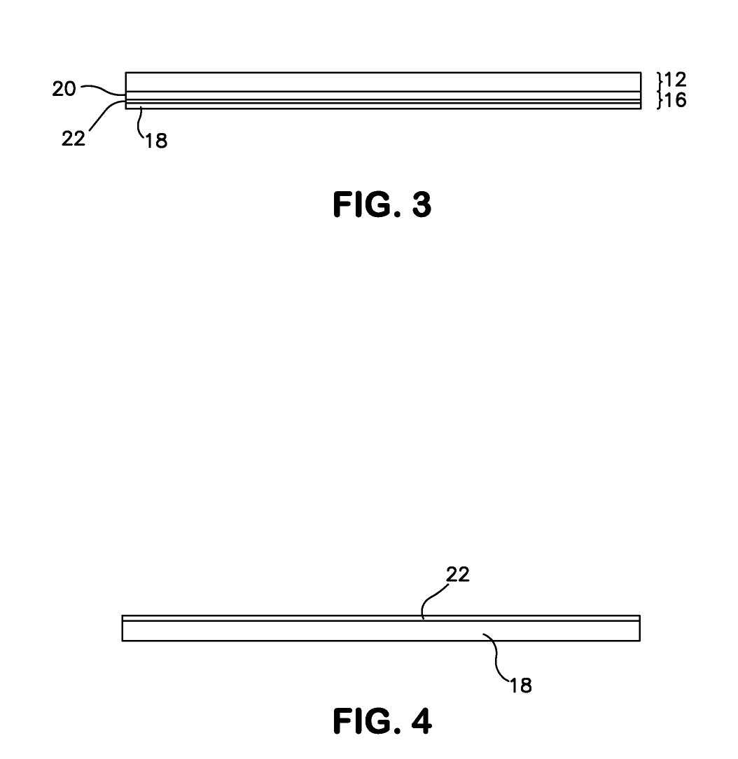

Referring to FIG. 3, one embodiment of a backing material 16 made in accordance with the present disclosure is illustrated. As shown, the backing material 16 is positioned adjacent to the semiconductor material 12 contained within a photovoltaic device.

As illustrated, the backing material 16 comprises a layer 20 containing an ethylene-vinyl acetate copolymer bonded to a polymer film 18, which may comprise a polyester film. In order to attach the polymer film 18 to the layer 20, a bonding layer 22 is positioned in between the layer 20 and the polymer film 18. As shown in FIG. 4, in one embodiment, the bonding layer 22 may comprise a coating which is applied to the polymer film 18 prior to laminating the film to the layer containing the ethylene-vinyl acetate copolymer.

In accordance with the present disclosure, the bonding layer or coating 22 comprises a block copolymer in conjunction with a coupling agent. The block copolymer, for instance, contains at least first polymer blocks and second polymer blocks. The first polymer blocks are capable of attaching to the polymer film. The coupling agent, on the other hand, may comprise a silane that is capable of chemically reacting with the second polymer blocks and chemically reacting with at least one constituent contained within the layer containing the ethylene-vinyl acetate copolymer. In this manner, the polymer film becomes securely bonded to the layer containing the ethylene-vinyl acetate copolymer.

In one embodiment, the block copolymer contained within the coating comprises a polyester block copolymer for use in conjunction with a polyester film. When applied to the polymer film as a coating solution and heated, for instance, the polyester polymer blocks have been found to attach to the polyester film. It is believed, for instance, that the polyester blocks become absorbed or otherwise integrated into the film structure. The second polymer blocks contained in the block copolymer, on the other hand, remain on the surface of the film for reaction with the coupling agent.

The second polymer blocks contained in the block copolymer can vary depending upon the particular application and the desired result. In one particular embodiment, for instance, the block copolymer comprises polyester polymer blocks in conjunction with polyethylene glycol polymer blocks. For instance, such block copolymers are disclosed in UK Patent No. 1,092,435, filed on May 15, 1964 entitled “Copolyesters”, which is incorporated herein by reference. Polyester block copolymers are also commercially available from the Clariant Corporation under the trade names MILEASE T or under HYDROPERM T. Such polyester block copolymers have been used in the past as a textile finishing agent to impart soil release, anti-static properties and increased moisture absorbency to polyester fabrics.

Polyester and polyethylene glycol block copolymers are generally hydrophilic polymers that are non-ionic. The polyester segments may be made from any suitable polyester, such as polyethylene terephthalate, poly(tetramethylene terephthalate), poly(1,4-bis-methylenecyclohexane terephthalate), poly(ethylene naphthalene-2,6-dicarboxylate) or poly(ethylene diphenoxyethane-4,4′-dicarboxylate).

The polyethylene glycol segments can have an average molecular weight of at least about 300, such as from about 300 to about 6000, such as from about 1000 to about 4000.

Instead of or in addition to using polyethylene glycol as the second polymer blocks, the block copolymer may also contain various other polymer blocks. For instance, the block copolymer may contain any suitable polyoxyalkylene glycol having a molecular weight as described above. Suitable polyoxyalkylene groups include polyoxyethylene, polyoxypropylene, polyoxytrimethylene, polyoxytetramethylene, polyoxybutylene, and copolymers thereof. Still further polymer blocks that may be incorporated into the block copolymer include urethane blocks, vinyl blocks, and polyethylene blocks, particularly linear low density polyethylene blocks. Particular polymer blocks that may be used to construct the second polymer blocks in the block copolymer include poly(vinyl alcohol), poly(vinyl methyl ether), poly(N,N-dimethylacrylamide), methylcellulose, or hydroxyethylcellulose.

The coupling agent used in conjunction with the block copolymer generally comprises any suitable coupling agent capable of reacting with the second polymer blocks and a constituent contained in an adjacent layer, such as in a layer containing an ethylene-vinyl acetate copolymer. As described above, in one embodiment, the coupling agent comprises a silane. In one particular embodiment, for instance, the silane may comprise a glycidoxy silane. Suitable silane coupling agents, for instance, are available from the Dow Corning Corporation. One particular silane marketed under the trade name Z-6040 by the Dow Corning Corporation contains reactive glycidoxy and methoxy groups. More particularly, the above silane is designated as 3-glycidoxy propyltrimethoxysilane.

It should be understood, however, that various other organofunctional silanes may also be used in the present disclosure. The silane, for instance, may comprise an amine silane including a styrylamine silane, a methacrylate silane, a vinyl silane, and/or a chloroalkyl silane.

The coupling agent incorporated into the bonding layer chemically reacts or otherwise attaches to the second polymer blocks on the block copolymer. The coupling agent also reacts with at least one constitutent in the opposing layer. For instance, if the opposing layer contains an ethylene-vinyl acetate copolymer, the coupling agent may attach directly to the copolymer. The layer containing the ethylene-vinyl acetate copolymer, however, may also contain various other functional groups that will attach to the coupling agent. For instance, a silane additive can also be incorporated into the layer containing the ethylene-vinyl acetate copolymer. In this manner, the silane contained within the bonding layer can chemically react with the silane contained in the opposing layer. In still other embodiments, the ethylene-vinyl acetate copolymer or another component in the adjacent layer may contain various functional groups that are chemically reactive with the coupling agent.

The relative amounts of the components in the bonding layer or coating can vary depending upon various factors. For instance, the amount may depend upon the particular block copolymer or coupling agent selected. The amounts also may vary depending upon the type of polymer film being coated and the type of substrate being laminated to the polymer film. In general, for instance, the block copolymer may be present in the bonding layer in an amount from about 40% to about 99% by weight, such as from about 60% to about 99% by weight, such as from about 70% to about 99% by weight. The coupling agent, on the other hand, may be present in an amount from about 0.1% to about 60% by weight, such as from about 1% to about 30% by weight. In one particular embodiment, the coating or bonding layer only contains the block copolymer in conjunction with the coupling agent. In other embodiments, however, other various components may be present.

The bonding layer may be formed on the polymer film using any suitable technique or method. In one embodiment, the components of the bonding layer are contained in an aqueous composition and applied to the polymer film while the polymer film is being formed. The coating composition, for instance, can have about 1% to about 10% solids, such as from about 1.5% to about 6% solids. For example, in one embodiment, the coating composition may contain the block copolymer in an amount from about 1.5% solids to about 4% solids and may contain the coupling agent in an amount of about 0.1% solids to about 2.0% solids. Adding the block copolymer in lesser amounts may not provide sufficient bonding strength. Applying the block copolymer in greater amounts, however, may prevent some of the polyester blocks from being absorbed by the film.

Of particular advantage, only relatively small amounts of the coating composition need be applied to the polymer film for providing suitable adhesion to an adjacent layer. For instance, the coating composition can be applied to the film in an amount from about 0.01 lbs/1000 ft² to about 0.1 lbs/1000 ft². Once applied to the polymer film, the film can be stretched in one or more directions and heated causing the coating composition to dry. The resulting coating on the film, in one embodiment, can be present in an amount from about 1×10⁻³ lbs/1,000 ft² to about 8×10⁻³ lbs/1,000 ft², such as from about 2×10⁻³ lbs/1,000 ft ² to about 5×10⁻³ lbs/1,000 ft².

in the embodiment illustrated in FIG. 4, only one side of the polymer film 18 is coated with the bonding layer 22. It should be understood, however, that in other embodiments both sides of the polymer film may be coated. In this manner, the polymer film can be laminated to the same or different substrates on either side. When forming photovoltaic devices, for instance, it may be useful to coat both sides of the polymer film in order to bond the film to a layer containing an ethylene-vinyl acetate copolymer on one side and to various electrical devices, such as a junction box, on the opposing side. The junction box, for instance, may be used in order to direct the electric current being created by the photovoltaic device to a downstream end use.

The polymer film 18 as shown in FIG. 4 can generally comprise any suitable polymer. For instance, polyester films are particularly well suited for use in the present disclosure. The polyester used to construct the film may comprise polyethylene terephthalate, polyethylene naphthalate or polybutylene terephthalate. The polymer film may also comprise copolyesters, such as polyethylene terephthalate isophthalate. Generally, any polyester film based on a polymer resulting from polycondensation of a glycol or diol with a dicarboxylic acid (or its ester equivalent) such as terephthalic acid, isothalic acid, sebacic acid, malonic acid, adipic acid, azelaic acid, glutaric acid, suberic acid, succinic acid, or mixtures thereof. Suitable glycols include ethylene glycol, diethylene glycol, polyethylene glycol, and polyols such as butanediol and the like. Mixtures of two or more of the foregoing are also suitable.

Any of the above based polymer films can contain conventional additives such as antioxidants, delusterants, pigments, fillers such as silica, calcium carbonate, kaolin, titanium dioxide, antistatic agents and the like or mixtures thereof. In one embodiment, for instance, a filler may be present in the polymer film sufficient to colorize the film and increase the opacity of the film. In one embodiment, for instance, the film can include a filler to make the film have a white appearance. One filler that may be used, for instance, is barium sulfate. Barium sulfate may be present in the film in an amount from about 5% to about 30% by weight.

The films may be produced by any well known technique in the art. For example, polyester is typically melted and extruded as an amorphous sheet onto a polished revolving casting drum to form a cast sheet of the polymer. The sheet is quickly cooled and then stretched or oriented in one or more directions to impart strength and toughness to the film. For instance, the sheet can be uniaxially stretched or biaxially stretched.

During extrusion, the temperature of the film is generally below about 300° C. For instance, the temperature during extrusion can be from about 275° C. to about 295° C.

Stretching of the film can generally occur as the film is being produced, although stretching can also be conducted offline. Biaxial stretching, for instance, is generally carried out in succession, but can take place simultaneously. When done in succession, stretching typically first takes place longitudinally (in the machine direction) and then transversely (in the transverse direction perpendicular to the machine direction). Stretching the film leads to spatial orientation of the polymer chains. The longitudinal stretching can be carried out with the aid of two rolls rotating at different speeds corresponding to the desired stretching ratio. For the transverse stretching, an appropriate tenter frame can be used in which the film is clamped at the two edges and then drawn towards the two sides at an elevated temperature.

Generally, stretching occurs at a temperature range of from about the second order transition temperature of the polymer to below the temperature at which the polymer softens and melts. In one embodiment, for instance, longitudinal stretching can be carried out at a temperature in the range of from about 80° C. to about 130° C., while the transverse stretching can be carried out at a temperature in the range of from about 90° C. to about 150° C.

The longitudinal stretching ratio can generally be in the range of from about 2:1 to about 6:1, such as from about 2:1 to about 5:1. The transverse stretching ratio is also generally from about 2:1 to about 6:1, such as from about 3:1 to about 5:1.

Where necessary, the film can be further heat treated after stretching to lock-in the properties by further crystallizing the film. The crystallization imparts stability and good tensile properties to the film. Heat treatment, for instance, can generally be conducted at a temperature of from about 150° C. to about 250° C., such as from about 190° C. to about 240° C. Coated films of the present disclosure, for instance, can be exposed to heat at a temperature of from about 210° C. to about 250° C. for a period of from about 1 to about 20 seconds.

In order to coat the film in accordance with the present disclosure, in one embodiment, the coating composition is applied to the film in-line. In particular, the coating composition is applied to the film while the film is being produced and before the film has been completely stretched or heat set. For instance, in one embodiment, the coating composition can be applied to the polymer film after corona treatment and prior to stretch orientation. In one particular embodiment, for instance, the coating composition can be applied to the film in-line by means of an aqueous dispersion after the longitudinal stretching step but prior to the transverse stretching step.

In addition to in-line coating, the coating composition can also be applied to the film off-line. Thus, the coating composition can be applied to the film after the film has been produced and cooled. When coating both sides of the film, for instance, one side of the film can be coated in-line, while the other side of the film can be coated off-line.

The resulting coated film can be used in numerous and different applications. As shown in FIGS. 1-3, for instance, in one embodiment the film can be laminated to a layer containing an ethylene-vinyl acetate copolymer and used as a backing material for a photovoltaic device. It should be appreciated, however, that the coated film can be laminated to other various devices and structures.

These and other modifications and variations to the present invention may be practiced by those of ordinary skill in the art, without departing from the spirit and scope of the present invention, which is more particularly set forth in the appended claims. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed:

1. A coated film comprising:
a polyester film having a first side and a second side; and
a coating on the first side of the polyester film, the coating comprising a block copolymer containing at least first polymer blocks and second polymer blocks, the first polymer blocks comprising polyester blocks, the polyester blocks being attached to the first side of the polyester film, the coating further comprising a silane, the silane including a moiety that is chemically reactive with the second polymer blocks contained in the block copolymer.

2. A coated film as defined in claim 1, wherein the silane comprises a glycidoxy silane.

3. A coated film as defined in claim 1, wherein the silane comprises an amino silane.

4. A coated film as defined in claim 1, wherein the second polymer blocks comprise polyethylene glycol blocks.

5. A coated film as defined in claim 1, wherein the second polymer blocks comprise urethane blocks, vinyl blocks, or polyethylene blocks.

6. A coated film as defined in claim 1, wherein the polyester film is at least uniaxially stretched.

7. A coated film as defined in claim 1, wherein the polyester film is biaxially stretched.

8. A coated film as defined in claim 1, wherein the coating contains the block copolymer in an amount from about 40% to about 99.9% by weight and contains the silane in an amount from about 0.1% to about 60% by weight.

9. A coated film as defined in claim 1, wherein the coating is present on the first side of the polyester film in an amount from about 1×10⁻³ lbs/1,000 ft² to about 8×10⁻³ lbs/1,000 ft².

10. A coated film as defined in claim 9, wherein the coating contains the block copolymer in an amount from about 70% to about 99% by weight.

11. A laminate comprising a layer containing an ethylene-vinyl acetate copolymer bonded to the coated film defined in claim 1, the layer being bonded to the first side of the polyester film by the coating.

12. A coated film as defined in claim 7, wherein the coating is formed by applying a coating composition onto the polyester film before the film has been completely stretched.

13. A laminate comprising:
a polyester film having a first side and a second side;
a polymeric layer; and
a bonding layer positioned between the first side of the polyester film and the polymeric layer, the bonding layer comprising a block copolymer containing at least first polymer blocks and second polymer blocks, the first polymer blocks comprising polyester blocks, the bonding layer further comprising a silane, the bonding layer attaching the first side of the polyester film to the polymeric layer.

14. A laminate as defined in claim 13, wherein the polymeric layer contains functional groups and wherein the silane contained in the bonding layer chemically reacts with the second polymer blocks located on the block copolymer and with the functional groups contained in the polymeric layer.

15. A laminate as defined in claim 13, wherein the silane comprises a glycidoxy silane.

16. A laminate as defined in claim 13, wherein the silane comprises an amino silane.

17. A laminate as defined in claim 13, wherein the second polymer blocks comprise polyethylene glycol blocks.

18. A laminate as defined in claim 13, wherein the bonding layer contains the block copolymer in an amount from about 40% to about 99% by weight and contains the silane in an amount from about 0.1% to 60% by weight, and wherein the bonding layer is present on the first side of the polyester film in an amount from about 1×10⁻³ lbs/1,000 ft² to about 8×10⁻³ lbs/1,000 ft².

19. A laminate as defined in claim 13, wherein a bond strength between the first side of the polyester film and the polymeric layer has an initial strength of at least about 50 N/15 mm.

20. A laminate as defined in claim 19, wherein the bond strength between the first side of the polyester film and the polymeric layer is at least about 50% of the initial bond strength after exposure to an atmosphere at 85% relative humidity at 85° C. for 1,000 hours.

21. A laminate as defined in claim 13, wherein the polyester blocks contained in the block copolymer are attached to the first side of the polyester film and wherein the silane reacts with the second blocks of the block copolymer and with the polymeric layer.

22. A photovoltaic device comprising:
a solar cell having a back panel, the back panel comprising the laminate defined in claim 13.

23. A laminate as defined in claim 13, wherein the polymeric layer contains an ethylene-vinyl acetate copolymer.

24. A laminate as defined in claim 13, wherein the polymeric layer comprises a polyolefin, an ionomer, or an elastomer.

25. A coated film comprising:
a polyester film having a first side and a second side; and
a coating on the first side of the polyester film, the coating comprising a block copolymer containing at least first polymer blocks and second polymer blocks, the first polymer blocks comprising polyester blocks, the second polymer blocks comprising polyethylene glycol blocks, urethane blocks, vinyl blocks, or polyethylene blocks, the coating further comprising a silane, the block copolymer being present in the coating in an amount from about 40% to about 99.9% by weight and the silane being present in the coating in an amount from about 0.1% to about 60% by weight, the silane comprising a glycidoxy silane or an amino silane.
